(19) United States
(12) Patent Application Publication
(10) Pub. No.: US 2015/0198893 A1
(43) Pub. Date: Jul. 16, 2015

(54) AMPLIFICATION APPARATUS, ANTI-VIBRATION APPARATUS, LITHOGRAPHY APPARATUS, AND ARTICLE MANUFACTURING METHOD

(71) Applicant: CANON KABUSHIKI KAISHA, Tokyo (JP)

(72) Inventor: Tatsuro Kato, Tokyo (JP)

(21) Appl. No.: 14/593,381

(22) Filed: Jan. 9, 2015

(30) Foreign Application Priority Data
Jan. 15, 2014 (JP) 2014-005069

(51) Int. Cl. G03F 7/20; H03F 1/30

(52) U.S. Cl. CPC G03F 7/7015; H03F 1/30; H03F 2200/153; H03F 2200/393; H03F 2200/462

(57) ABSTRACT

Provided is an amplification apparatus that outputs an output signal corresponding to an input signal via an amplifier, and comprises a detector that is installed separately from a main body, which includes the amplifier, and is configured to detect the output signal outputted from the main body, and to feed back the output signal to the input signal.

### BACKGROUND OF THE INVENTION

1. Field of the Invention

The present invention relates to an amplification apparatus, an anti-vibration apparatus, a lithography apparatus, and an article manufacturing method.

2. Description of the Related Art

A lithography apparatus patterns a substrate by drawing, exposing or the like, in a lithography step included in manufacturing steps for manufacturing articles such as semiconductor devices, liquid crystal display devices, and the like. In particular, in an electron beam drawing apparatus or a semiconductor exposure apparatus, it is not desirable that outside vibration is applied to a processing unit related directly to pattering processes, such as a drawing unit, exposing unit or the like, since the pattering precision may be influenced. For example, in a semiconductor exposure apparatus, there is possibility that overlay precision will be reduced if floor vibration is transmitted to an interferometer for measuring a position of a stage device that holds a substrate, and a lens barrel base for disposing a lens barrel that generates exposure light. Therefore, the lithography apparatus is typically provided with an anti-vibration apparatus using an air actuator and the like. The anti-vibration apparatus supports the lens barrel base at a low natural frequency of several Hz in order to suppress the transmission of the floor vibration, and simultaneously performs a positioning control. Japanese Patent Laid-Open No. H8-111998 discloses a positioning apparatus that outputs a current value supplied to an anti-vibration apparatus for positioning control via a current amplifier (amplification apparatus). The current amplifier performs current control that detects the current value supplied to the anti-vibration apparatus and feeds back the current value to a current command value.

In the current amplifier disclosed in Japanese Patent Laid-Open No. H8-111998, the internal temperature is changed due to heat generated on circuits at the inside of a main body. Consequently, there is a case where the current value is changed by changing the properties of the components included in the current amplifier. Hereinafter, this change in the current value due to the change in the temperature is referred to as “drift”. In particular, the drift generated at a current detector in the current amplifier cannot be suppressed by the feedback in a main body (current amplifier unit) of the current amplifier, and thereby is included in the output of the current amplifier as an error. Conventionally, this drift had a small level amount that could be ignored. However, in recent years, an anti-vibration at a lower natural frequency that is less than or equal to 1 Hz is required in a lithography apparatus, in terms of precision, for example, as higher overlay precision is required. At the same time, if the natural frequency is set low, a control gain for positioning needs to be set low, and a force generated by drift cannot be suppressed, resulting in larger vibration amplitude of the lens barrel base. For example, in a lithography apparatus that holds a lens barrel using a lens barrel base, a stopper is provided for limiting the movable range of the lens barrel base in order to prevent collision with the lens barrel and a substrate. However, this may cause a collision between the lens barrel base and the stopper due to larger vibration amplitude of the lens barrel base.

### SUMMARY OF THE INVENTION

The present invention provides, for example, an amplification apparatus advantageous in terms of the suppression of an influence by changing in temperature inside a main body (current amplifier unit).

According to an aspect of the present invention, an amplification apparatus for outputting an output signal corresponding to an input signal via an amplifier is provided that comprises a detector that is installed separately from a main body, which includes the amplifier, and is configured to detect the output signal outputted from the main body, and to feed back the output signal to the input signal.

Further features of the present invention will become apparent from the following description of exemplary embodiments (with reference to the attached drawings).

### BRIEF DESCRIPTION OF THE DRAWINGS

FIG. 1 illustrates a configuration of an electron beam drawing apparatus according to one embodiment of the present invention.

FIG. 2 is a block diagram illustrating a configuration of an anti-vibration apparatus according to one embodiment.

FIG. 3 is a block diagram illustrating a configuration of an anti-vibration apparatus according to another embodiment.

### DESCRIPTION OF THE EMBODIMENTS

Hereinafter, preferred embodiments of the present invention will be described with reference to the drawings.

Firstly, a description will be given of a configuration of an amplification apparatus according to one embodiment of the present invention. The amplification apparatus according to the present embodiment may be applied to, for example, an anti-vibration apparatus that suppresses transmission of a vibration from a vibration source to an object using a driving unit such as an air actuator and the like. In addition, the anti-vibration apparatus may be employed, for example, in a lithography apparatus such as an electron beam drawing apparatus, a semiconductor exposure apparatus or the like. Hereinafter, in the present embodiment, a description will be given by taking an amplification apparatus employed in an electron beam drawing apparatus as an example.

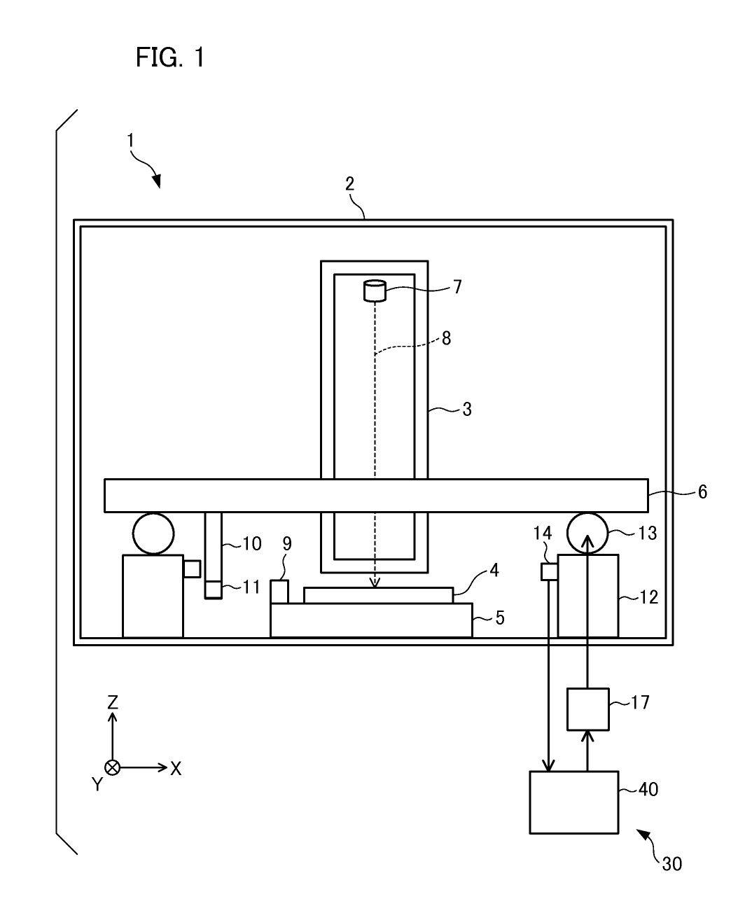

FIG. 1 is a schematic diagram illustrating a configuration of an electron beam drawing apparatus (hereinafter simply referred to as “drawing apparatus”) 1 according to the present embodiment. The drawing apparatus 1 draws a predetermined pattern on a predetermined position of a substrate 4 by deflecting a charged particle beam and executing control of the blanking (irradiation OFF) of the charged particle beam. Here, a charged particle beam denotes an electron beam, an ion beam, or the like. However, the electron beam is used as the charged particle beam of the present embodiment. The substrate 4 is, for example, a wafer configured from monocrystalline silicon, and has a photosensitive resist coated onto a surface thereof. In FIG. 1, the Z axis is aligned in a nominal irradiation direction of the electron beam to the substrate 4, and the X axis and Y axis are orthogonally aligned in a plane that is perpendicular to the Z axis.

The drawing apparatus 1 is provided with an electron optical lens barrel 3 as a processing unit that performs drawing, a stage 5 on which the substrate 4 is mounted, a lens barrel base 6 that holds the electron optical lens barrel 3, a supporting unit 12 that supports the lens barrel base 6 via a driving unit 13, and a controller 40. The electron optical lens barrel 3 includes an electron gun 7, a deflecting system, and an optical system (not shown) therein. The deflecting system and the optical system execute the control (blanking control) of an electron beam 8 emitted from the electron gun 7 to the substrate 4 that is disposed onto the stage 5 and is positioned at a downstream side of the electron gun 7. Note that the inside of the electron optical lens barrel 3 is maintained in a high vacuum using a vacuum pumping system (not shown). The stage 5 holds the substrate 4, for example, by electrostatic attraction, and is movable in the directions of the X axis and Y axis. In addition, the stage 5 is provided with a reflective mirror 9 located on the side edge thereof. The lens barrel base 6 is provided with a support 10 for an interferometer, and the interferometer 11 is disposed to a top of the support 10. The interferometer 11 emits a laser beam to a reflecting mirror 9, receives the reflected light, and thereby detects a position of the stage 5 in directions of the X axis and Y axis. Here, the electron optical lens barrel 3, the stage 5, and the lens barrel base 6 are disposed to the inside of a vacuum chamber 2 maintained in a vacuum by a vacuum pumping system (not shown). The controller 40 is configured to control the operations of each component in the electron optical lens barrel 3, the stage 5, the anti-vibration apparatus 30 and the like. The controller 40 moves the stage 5 by a step-and-repeat operation or step-and-scan operation to appropriately deflect the emitted electron beam, as standard operations for drawing, resulting in drawing a pattern at a shot (drawing area) on the substrate 4.

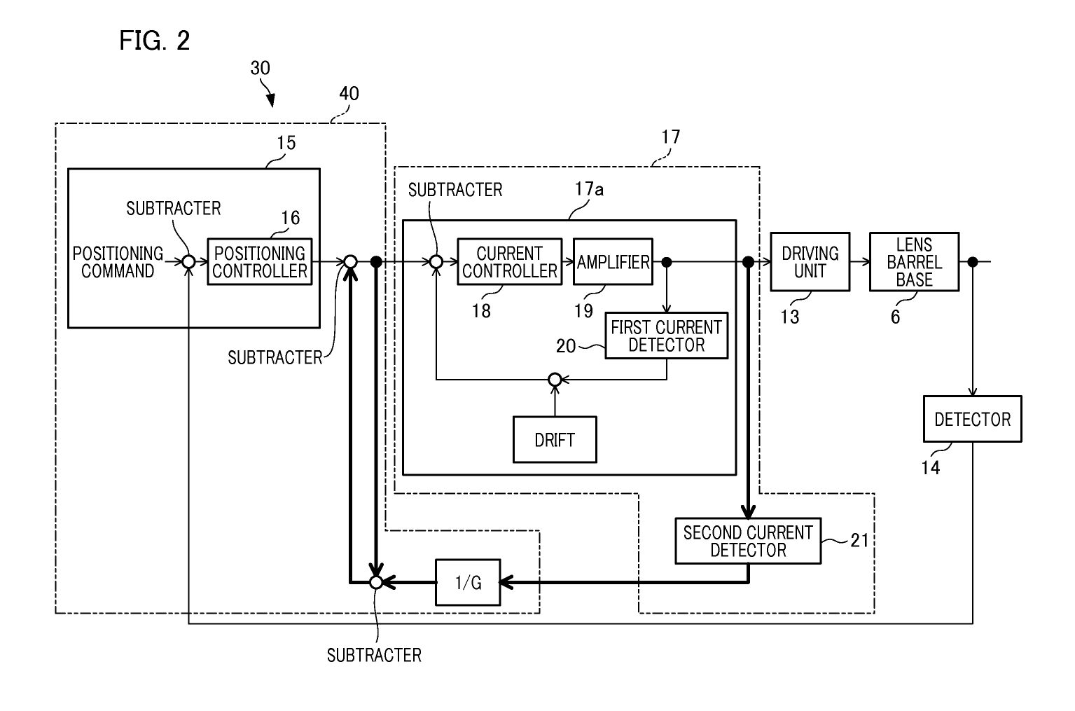

Next, a detailed description will be given of an anti-vibration apparatus 30 and an amplification apparatus included in the anti-vibration apparatus 30. FIG. 2 is a block diagram illustrating a configuration of an anti-vibration apparatus 30, in which the same reference numerals are provided to each of the components of the same configuration as each of the components shown in FIG. 1. The anti-vibration apparatus 30 is disposed, for example, in order to suppress transmission of floor vibration to the lens barrel base 6 as an object. The anti-vibration apparatus 30 comprises driving units 13, a detector 14, a controller 40, and an amplification apparatus 17. The driving units 13 is, for example, an air actuator, and are disposed at least three positions between the lens barrel base 6 and a plurality of supporting units 12. The driving units 13 support and position the lens barrel base 6 on a base (not illustrated) at low natural frequency. The driving units 13 are not limited to an air actuator but may be a linear motor. If the combination of the air actuator and the linear motor is employed, for example, the linear motor may act as the driving unit 13. Here, in order to simplify the description, a description will be given of positioning control to one of the plurality of driving units 13. The detector 14 is, for example, a displacement sensor. The plurality of detectors 14 is disposed near the driving units 13 in the plurality of supporting units 12 respectively, and detects relative displacement of the lens barrel base 6 and the supporting unit 12 in which each of the detectors 14 are disposed. The current command generator 15 is constituted, for example, in the controller 40, inputs a deviation between the relative displacement detected by the detectors 14 and the position command transmitted to the driving units 13, to the positioning controller 16, and generates a current command value for the driving unit 13.

The amplification apparatus 17 amplifies a current command value (input signal), and outputs a current value (output signal) to the driving unit 13. The driving unit 13 applies a control force based on the current value of drive signal, and provides a displacement to the lens barrel base 6. The amplification apparatus 17 includes a main body (current amplifier unit) 17a having a current controller 18, an amplifier 19, a first current detector 20, and a housing, and a second current detector 21. Firstly, the first current detector (internal detector) 20 detects a current value transmitted to the driving units 13 and feeds back the detected current value to the current command value. Next, the current controller 18 calculates an input signal for the amplifier 19. Then, the amplifier 19 outputs the amplified current value. The second current detector (detector) 21 differs from the first current detector 20, and is disposed to the outside of the main body 17a, that is, is disposed separately from the main body 17a. The second current detector 21 detects a current value outputted from the main body 17a. In this case, the controller 40 calculates a deviation between the current command value obtained from the current command generator 15 and a signal obtained by multiplying the current value obtained from the second current detector 21 by inverse characteristic 1/G of the main body 17a. Here, the multiplication by inverse characteristic 1/G of the main body 17a is for converting the current value into the level of the current command value. Finally, the obtained deviation signal is fed back to the current command value, and then is inputted to the main body 17a.

In a conventional amplification apparatus that has basic components corresponding to the main body 17a of the amplification apparatus 17, an output value in the first current detector 20 for detecting the output signal from the amplifier 19 is often affected, if drift (a change in the current value due to the change in the temperature inside) has occurred in the inside of the amplification apparatus as shown in FIG. 2. This often has unintended results, such as an increase in an amplitude of an output signal and the like. In contrast, in the present embodiment, in addition to the first current detector 20, the second current detector 21 is disposed outside the housing of the main body 17a, which detects an output signal from the amplifier 19 (in this case, from the main body 17a) similarly to the first current detector 20. Therefore, even if drift has occurred inside the main body 17a, unintended results such as those mentioned above may be suppressed since the second current detector 21 is not affected by the drift.

As mentioned above, according to the present embodiment, an amplification apparatus advantageous in terms of the suppression of the influence by changing in temperature inside the main body (i.e. inside the housing) can be provided. Further, an anti-vibration apparatus advantageous in terms of the precision of the positioning control can be provided by using the amplification apparatus according to the present embodiment. Furthermore, a lithography apparatus advantageous in terms of the patterning precision can be provided by using the anti-vibration apparatus according to the present embodiment.

While the above description has been given of the case where the amplification apparatus 17 includes the current amplifier, the amplification apparatus 17 of the present invention is not limited thereto, but may include, for example, a voltage amplifier. In this case where the amplification apparatus includes the voltage amplifier, a voltage command value takes the place of the current command value described above, and a voltage value takes the place of the current value described above.

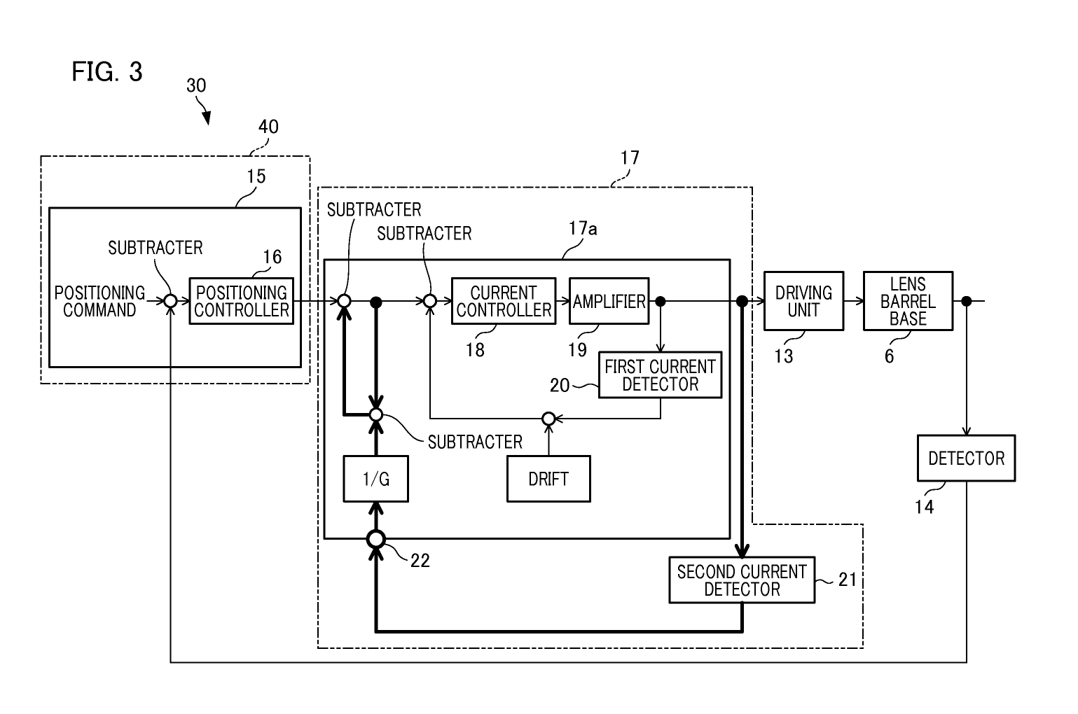

In addition, the controller 40 performs a process that calculates the deviation between the current command value obtained from the current command generator 15 and the signal obtained by multiplying the current value obtained from the second current detector 21 by the inverse characteristic 1/G of the main body 17a in the above description. However, this invention is not limited thereto, but the calculating process may be performed in the inside of the main body 17a of the amplification apparatus 17 as shown in FIG. 3. In this case, a terminal 22 is disposed in the main body 17a and the current value detected by the second current detector 21 is inputted to the inside via the terminal 22. Furthermore, while a description has been given of the case where the current value from the second current detector 21 is multiplied by the inverse characteristic 1/G of the main body 17a in order to converting the current value into the level of the current command value, the second current detector 21 may have this converting function itself.

### (Article Manufacturing Method)

An article manufacturing method according to an embodiment of the present invention is preferred in manufacturing an article such as a micro device such as a semiconductor device or the like, an element or the like having a microstructure, or the like. The article manufacturing method may include a step of forming a pattern (e.g., latent image pattern) on an object (e.g., substrate on which a photosensitive material is coated) using the aforementioned lithography apparatus; and a step of processing (e.g., step of developing) the object on which the latent image pattern has been formed in the previous step. Furthermore, the article manufacturing method may include other known steps (oxidizing, film forming, vapor depositing, doping, flattening, etching, resist peeling, dicing, bonding, packaging, and the like). The device manufacturing method of this embodiment has an advantage, as compared with a conventional device manufacturing method, in at least one of performance, quality, productivity and production cost of an article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-005069 filed on Jan. 15, 2014, which is hereby incorporated by reference herein in its entirety.

What is claimed is:

1. An amplification apparatus for outputting an output signal corresponding to an input signal via an amplifier, the amplification apparatus comprising:
a detector that is installed separately from a main body, which includes the amplifier, and is configured to detect the output signal outputted from the main body, and to feed back the output signal to the input signal.

2. The amplification apparatus according to claim 1, comprising an internal detector that is installed in the main body and is configured to detect the output signal outputted from the amplifier,
wherein the detector differs from the internal detector.

3. The amplification apparatus according to claim 1, wherein a deviation is obtained between the output signal detected by the detector and the input signal, and
the deviation is fed back to the input signal.

4. The amplification apparatus according to claim 1, wherein the amplification apparatus is a current amplifier in which the input signal is a current command value and the output signal is a current value.

5. The amplification apparatus according to claim 1, wherein the amplification apparatus is a voltage amplifier in which the input signal is a voltage command value and the output signal is a voltage value.

6. An anti-vibration apparatus for suppressing transmission of a vibration from a vibration source to an object, the anti-vibration apparatus including:
a driving unit that is installed between the vibration source and the object, and provides a displacement; and
an amplification apparatus for outputting a driving signal as an output signal corresponding to an input signal to the driving unit via an amplifier,
wherein the amplification apparatus comprises a detector that is installed separately from a main body, which includes the amplifier, and is configured to detect the output signal outputted from the main body, and to feed back the output signal to the input signal.

7. A lithography apparatus for patterning a substrate,
the lithography apparatus including a processing unit for patterning as the object and an anti-vibration apparatus for suppressing transmission of a vibration from a vibration source to the processing unit, wherein the anti-vibration apparatus includes:
a driving unit that is installed between the vibration source and the processing unit, and provides a displacement; and
an amplification apparatus for outputting a driving signal as an output signal corresponding to an input signal to the driving unit via an amplifier,
wherein the amplification apparatus comprises a detector that is installed separately from a main body, which includes the amplifier, and is configured to detect the output signal outputted from the main body, and to feed back the output signal to the input signal.

8. A method of manufacturing an article, the method comprising:
patterning a substrate using a lithography apparatus for patterning a substrate, and
processing the patterned substrate to manufacture the article
wherein the lithography apparatus includes a processing unit for patterning as the object and an anti-vibration apparatus for suppressing transmission of a vibration from a vibration source to the processing unit,
wherein the anti-vibration apparatus includes:
a driving unit that is installed between the vibration source and the processing unit, and provides a displacement; and
an amplification apparatus for outputting a driving signal as an output signal corresponding to an input signal to the driving unit via an amplifier,
wherein the amplification apparatus comprises a detector that is installed separately from a main body, which includes the amplifier, and is configured to detect the output signal outputted from the main body, and to feed back the output signal to the input signal.
